(19) United States
(12) Patent Application Publication
(10) Pub. No.: US 2017/0294505 A1
(43) Pub. Date: Oct. 12, 2017

(54) GATE ELECTRODE STRUCTURE AND HIGH VOLTAGE SEMICONDUCTOR DEVICE HAVING THE SAME

(71) Applicant: DONGBU HITEK CO., LTD., Seoul (KR)

(72) Inventors: Hong Sik Shin, Gyeonggi-do (KR); Kwang Young Ko, Gyeonggi-do (KR)

(21) Appl. No.: 15/471,443

(22) Filed: Mar. 28, 2017

(30) Foreign Application Priority Data
Apr. 6, 2016 (KR) 1020160042123

(51) Int. Cl. H01L 29/06; H01L 29/66; H01L 21/762; H01L 29/78

(52) U.S. Cl. CPC H01L 29/0611; H01L 29/7816; H01L 29/66689; H01L 21/762

(57) ABSTRACT

A gate electrode structure and a high voltage semiconductor device having the same are disclosed. The gate electrode structure includes a gate insulation layer pattern disposed on a substrate, a gate electrode disposed on the gate insulating layer pattern and having at least one opening at a first side portion thereof, and at least one insulating pattern disposed in the at least one opening. The high voltage semiconductor device includes a drift region disposed in the substrate adjacent to the first side portion of the gate electrode, a drain region electrically connected with the drift region, and a source region disposed in the substrate adjacent to a second side portion of the gate electrode.

### CROSS-REFERENCE TO RELATED APPLICATION

This application claims the priority benefit of Korean Patent Application No. 10-2016-0042123, filed on Apr. 6, 2016, and all the benefits accruing therefrom under 35 U.S.C. §119, the contents of which are incorporated by reference in their entirety.

### BACKGROUND

The present disclosure relates to a gate electrode structure and a high voltage semiconductor device having the same.

A Metal Oxide Semiconductor Field Effect Transistor (MOSFET) may have relatively high input impedance compared to a bipolar transistor, providing a relatively large power gain and/or a relatively simple gate driving circuit. Further, the MOSFET may be a unipolar device having substantially no-time delay which may result from minority carrier storage and/or recombination while being turned off. The MOSFET may be applied to switching mode power supply devices, lamp ballasts, motor-driving circuits and the like. For example, a DMOSFET (Double Diffused MOSFET) manufactured by using a planar diffusion technology can be used.

A lateral double diffused metal oxide semiconductor (LDMOS) device may be applied to a very large scale integration (VLSI) process due to its relatively simple structure. Particularly, the LDMOS device may have relatively improved electrical characteristics compared to a vertical diffused MOS (VDMOS) device. For example, Korean Laid-Open Patent Publication No. 10-2006-0077006 to Lee Kyung Ho (published Jul. 5, 2006), which is commonly assigned with the present application, discloses a high voltage semiconductor device including a drift region and a drain region disposed in the drift region.

A portion of the drift region may be disposed under a side portion of a gate electrode. In such case, RC delay and interference with adjacent devices may be increased due to the parasitic capacitance between the gate electrode and the drift region.

### SUMMARY

The present disclosure provides a gate electrode structure capable of reducing a parasitic capacitance between a gate electrode and a drift region and a high voltage semiconductor device having the gate electrode structure.

In accordance with an aspect of the present disclosure, a gate electrode structure may include a gate insulation layer pattern disposed on a substrate; a gate electrode disposed on the gate insulating layer pattern and having at least one opening at a first side portion thereof; and at least one insulating pattern disposed in the at least one opening.

In accordance with some exemplary embodiments, the gate electrode structure may further include gate spacers disposed on side surfaces of the gate electrode.

In accordance with some exemplary embodiments, the at least one insulating pattern may be made of the same material as the gate spacers.

In accordance with some exemplary embodiments, the gate electrode may have at least one second opening disposed at a second side portion opposite to the first side portion.

In accordance with some exemplary embodiments, the gate electrode structure may further include at least one second insulating pattern disposed in the at least one second opening.

In accordance with some exemplary embodiments, the at least one opening may have a slit shape extending along a first side surface of the gate electrode.

In accordance with some exemplary embodiments, the gate electrode may have a plurality of openings disposed along a first side surface of the gate electrode and a plurality of insulating patterns may be each disposed in the plurality of the openings.

In accordance with another aspect of the present disclosure, a high voltage semiconductor device may include a gate insulation layer pattern disposed on a substrate; a gate electrode disposed on the gate insulating layer pattern; a drift region disposed in the substrate adjacent to a first side portion of the gate electrode; a drain region electrically connected with the drift region; and a source region disposed in the substrate adjacent to a second side portion of the gate electrode. The gate electrode may have at least one opening disposed at the first side portion and at least one insulating pattern may be disposed in the at least one opening.

In accordance with some exemplary embodiments, the at least one insulating pattern may be disposed on the gate insulating layer pattern.

In accordance with some exemplary embodiments, the at least one insulating pattern may be disposed over an edge portion of the drift region.

In accordance with some exemplary embodiments, the high voltage semiconductor device may further include gate spacers disposed on side surfaces of the gate electrode.

In accordance with some exemplary embodiments, the at least one insulating pattern may be made of the same material as the gate spacers.

In accordance with some exemplary embodiments, the at least one opening may have a slit shape extending along a first side surface of the gate electrode.

In accordance with some exemplary embodiments, the gate electrode may have a plurality of openings disposed along a first side surface of the gate electrode and a plurality of insulating patterns may be each disposed in the plurality of the openings.

In accordance with still another aspect of the present disclosure, a high voltage semiconductor device may include a gate insulation layer pattern disposed on a substrate; a gate electrode disposed on the gate insulating layer pattern; a first drift region disposed in the substrate adjacent to a first side portion of the gate electrode; a second drift region disposed in the substrate adjacent to a second side portion of the gate electrode; a drain region electrically connected with the first drift region; and a source region electrically connected with the second drift region. The gate electrode may have at least one first opening disposed at the first side portion and at least one second opening disposed at the second side portion; at least one first insulating pattern may be disposed in the at least one first opening; and at least one second insulating pattern may be disposed in the at least one second opening.

In accordance with some exemplary embodiments, the first and second insulating patterns may be disposed on the gate insulating layer pattern.

In accordance with some exemplary embodiments, the at least one first insulating pattern may be disposed over an edge portion of the first drift region, and the at least one second insulating pattern may be disposed over an edge portion of the second drift region.

In accordance with some exemplary embodiments, the high voltage semiconductor device may further include gate spacers disposed on side surfaces of the gate electrode.

In accordance with some exemplary embodiments, the first and second insulating patterns may be made of the same material as the gate spacers.

In accordance with some exemplary embodiments, the drain and source regions may be disposed in the first and second drift regions, respectively.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a gate electrode structure and a high voltage semiconductor device in accordance with an exemplary embodiment of the present disclosure;

FIG. 2 is a plan view illustrating a gate electrode and insulating patterns of FIG. 1;

FIG. 3 is a plan view illustrating another example of the gate electrode and the insulating patterns of FIG. 2;

FIG. 4 is a cross-sectional view illustrating a gate electrode structure and a high voltage semiconductor device in accordance with another exemplary embodiment of the present disclosure;

FIG. 5 is a plan view illustrating a gate electrode and first and second insulating patterns of the embodiment shown in FIG. 4; and

FIG. 6 is a plan view illustrating an alternative gate electrode with first and second insulating patterns corresponding to the embodiment shown in FIG. 4.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present disclosure are described in more detail with reference to the accompanying drawings. However, the present disclosure is not limited to the embodiments described below and is implemented in various other forms. Embodiments below are not provided to fully complete the present disclosure but rather are provided to fully convey the range of the present disclosure to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present disclosure, the regions and the layers are not limited to these terms.

Terminologies used below are used to merely describe specific embodiments, but do not limit the present disclosure. Additionally, unless otherwise defined here, all the terms including technical or scientific terms, may have the same meaning that is generally understood by those skilled in the art.

Embodiments of the present disclosure are described with reference to schematic drawings of ideal embodiments. Accordingly, changes in manufacturing methods and/or allowable errors may be expected from the forms of the drawings. Accordingly, embodiments of the present disclosure are not described being limited to the specific forms or areas in the drawings, and include the deviations of the forms. The areas may be entirely schematic, and their forms may not describe or depict accurate forms or structures in any given area, and are not intended to limit the scope of the present disclosure.

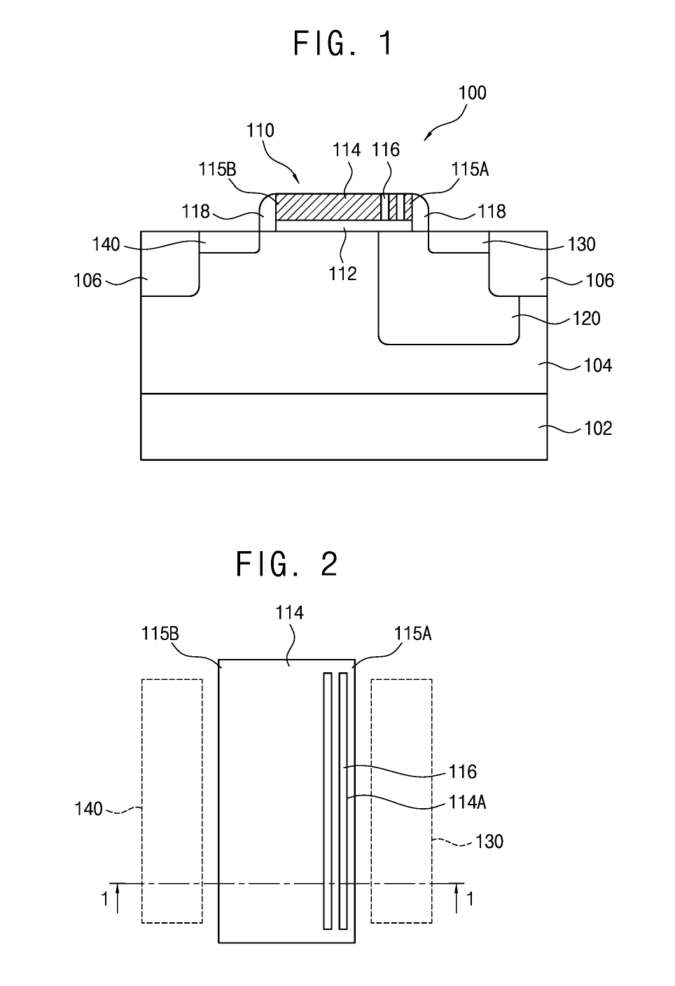

FIG. 1 is a cross-sectional view illustrating a gate electrode structure and a high voltage semiconductor device in accordance with an exemplary embodiment of the present disclosure, and FIG. 2 is a plan view illustrating a gate electrode and insulating patterns as shown in FIG. 1. FIG. 1 is a cross-sectional view of the device shown in FIG. 2, taken along line 1-1.

Referring to FIGS. 1 and 2, in accordance with an exemplary embodiment of the present disclosure, a high voltage semiconductor device 100 may include a gate electrode structure 110 disposed on a substrate 102. The gate electrode structure 110 may include a gate insulating layer pattern 112 disposed on the substrate 102 and a gate electrode 114 disposed on the gate insulating layer pattern 112. For clarity, some components (such as gate spacers 118) are not shown in FIG. 2.

Further, the high voltage semiconductor device 100 may include a first drift region 120 disposed in the substrate 102 adjacent to a first side portion 115A of the gate electrode 114, a drain region 130 electrically connected with the first drift region 120, and a source region 140 disposed in the substrate 102 adjacent to a second side portion 115B of the gate electrode 114 opposite to the first side portion 115A.

The substrate 102 may include a well region 104 having a first conductivity type, and the gate electrode structure 110 may disposed on the well region 104. The first drift region 120, the drain region 130 and the source region 140 may be disposed in the well region 104. Particularly, the drain region 130 may be disposed in the first drift region 120. Device isolation regions 106 may be disposed on both sides of the drain and source regions 130 and 140 as shown to prevent electrical contact with other components in or adjacent to substrate 102.

The device isolation regions 106 may be formed by a shallow trench isolation (STI) process. For example, trenches may be formed at surface portions of the substrate 102 and may be filled with an insulating material, such as silicon oxide and/or silicon nitride, so as to form the device isolation regions 106. After forming the device isolation regions 106, the well region 104 may be formed by an ion implantation process.

The first drift region 120, the drain region 130 and the source region 140 may have a second conductivity type. For example, when a p-type well region is used, the first drift region 120, the drain region 130 and the source region 140 may be n-type impurity regions. Alternatively, when an n-type well region is used, the first drift region 120, the drain region 130 and the source region 140 may be p-type impurity regions.

The drain region 130 and the source region 140 may be disposed adjacent to both sides of the gate electrode structure 110 and may be high concentration impurity regions having the second conductivity type. The first drift region 120 may be used to improve the breakdown voltage of the high voltage semiconductor device 100 and may have an impurity concentration lower than the drain region 130.

In accordance with an exemplary embodiment of the present disclosure, the gate electrode 114 may have openings 114A vertically formed at the first side portion 115A of the gate electrode 114, which is disposed adjacent to the first drift region 120, and insulating patterns 116 may be disposed in the openings 114A, as shown in FIG. 2. Particularly, the openings 114A may pass through the first side portion 115A of the gate electrode 114, and the insulating patterns 116 may be disposed on the gate insulating layer pattern 112.

The openings 114A may have a slit shape extending along a first side surface of the gate electrode 114, which is disposed adjacent to the drain region 130, as shown in FIG. 2, and may be filled with the insulating patterns 116. Meanwhile, the gate electrode structure 110 may include gate spacers 118 disposed on side surfaces of the gate electrode 114. The gate spacers 118 may be made of an insulating material such as silicon oxide and/or silicon nitride, and the insulating patterns 116 may be made of the same material as the gate spacers 118.

At the first side portion 115A of the gate electrode 114 and first drift region 120 effectively form a parallel plate capacitor separated by the dielectric insulating layer pattern 112. The insulating patterns 116 may be disposed over an edge portion of the first drift region 120, reducing the surface area of the top plate of this parallel plate capacitor such that the parasitic capacitance between the gate electrode 114 and the first drift region 120 is reduced. In detail, an area of the gate electrode 114 facing the edge portion of the first drift region 120 may be reduced by the insulating patterns 116, and the parasitic capacitance between the gate electrode 114 and the first drift region 120 may thus be reduced. Reducing this capacitance causes an accompanying decrease in the RC delay of the high voltage semiconductor device 100 and the interference with adjacent devices.

As shown in FIGS. 1 and 2, two insulating patterns 116 are used. However, the number of the insulating patterns 116 may be variously changed, and thus the scope of the present disclosure is not limited thereto. For example, in embodiments only one insulating pattern 116 may be used to reduce the parasitic capacitance.

The gate electrode structure 110 may be formed by film forming processes and patterning processes. For example, a gate insulating layer may be formed by a thermal oxidation process and a gate conductive layer may be formed by a chemical vapor deposition process. The gate insulating layer may be made of silicon oxide and the gate conductive layer may be made of impurity doped polysilicon.

The gate electrode 114 and the openings 114A may be formed by patterning the gate conductive layer, and the gate insulating layer pattern 112 may be formed by patterning the gate insulating layer.

After forming the gate electrode 114 and the gate insulating layer pattern 112, a second insulating layer may be formed on the substrate 102 by a chemical vapor deposition process, and an anisotropic etching process may be performed to form the gate spacers 118. For example, the gate spacers 118 may be made of silicon oxide and/or silicon nitride. Particularly, the openings 114A may be filled with the silicon oxide and/or silicon nitride while forming the second insulating layer, and the insulating patterns 116 may be obtained by the anisotropic etching process. That is, the insulating patterns 116 may be simultaneously formed with the gate spacers 118, and thus no additional processes for forming the insulating patterns 116 are required. As a result, an increase in manufacturing cost that may be caused by the insulating patterns 116 is prevented.

The first drift region 120 may be formed by an ion implantation process using dopants having the second conductivity type before the gate electrode structure 110 is formed. The drain region 130 and the source region 140 may be formed by an ion implantation process using dopants having the second conductivity type after the gate electrode structure 110 is formed.

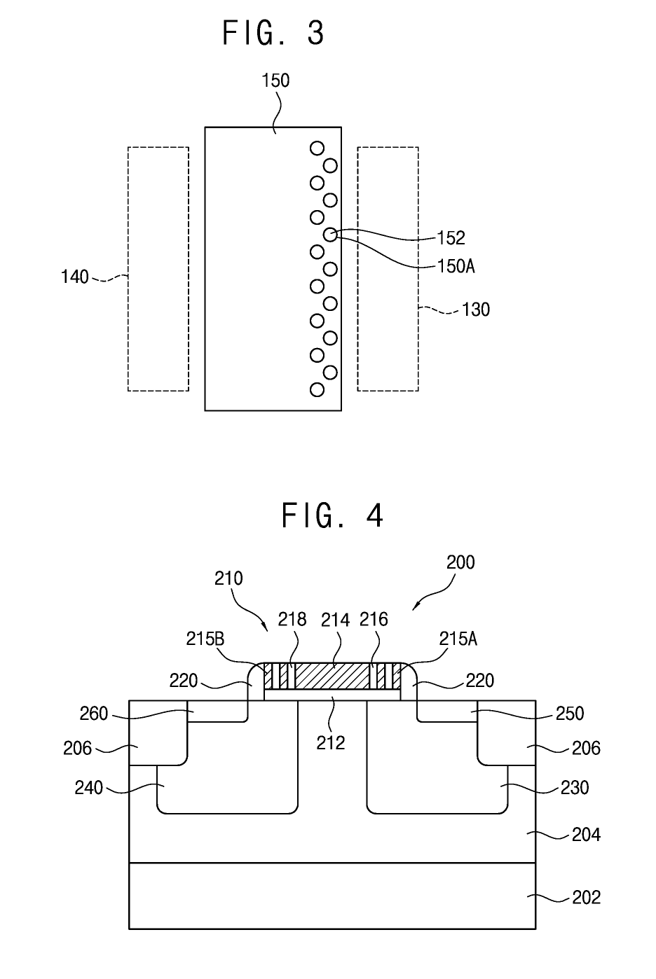

FIG. 3 is a plan view illustrating another example of an alternative embodiment of gate electrode and the insulating patterns.

Referring to FIG. 3, a gate electrode 150 may have a plurality of openings 150A disposed along a first side surface of the gate electrode 150 which is disposed adjacent to the drain region 130, and a plurality of insulating patterns 152 may be each disposed in the openings 150A.

As shown in FIG. 3, two rows of openings 150A and two rows of insulating patterns 152 are used. However, the numbers and positions of the openings 150A and the insulating patterns 152 may be variously changed, and thus the scope of the present disclosure is not limited thereto. For example, one row of openings 150A and one row of insulating patterns 152 may be used.

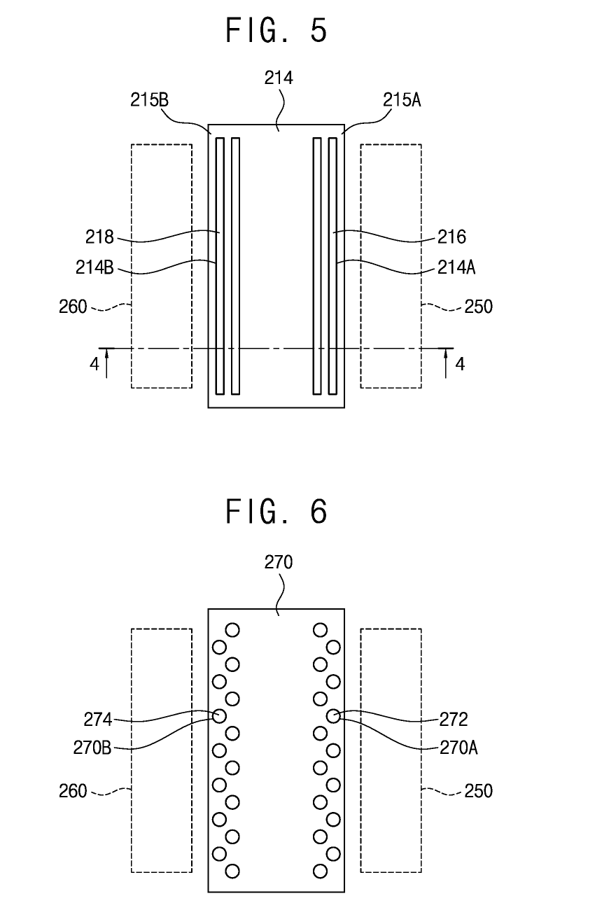

FIG. 4 is a cross-sectional view illustrating a gate electrode structure and a high voltage semiconductor device in accordance with another exemplary embodiment of the present disclosure, and FIG. 5 is a plan view illustrating a gate electrode and first and second insulating patterns as shown in FIG. 4. Line 4-4 of FIG. 5 indicates the cross-section along which FIG. 4 is taken.

Referring to FIGS. 4 and 5, in accordance with another exemplary embodiment of the present disclosure, a high voltage semiconductor device 200 may include a gate electrode structure 210 disposed on a substrate 202. The gate electrode structure 210 may include a gate insulating layer pattern 212 disposed on the substrate 202 and a gate electrode 214 disposed on the gate insulating layer pattern 212.

Further, the high voltage semiconductor device 200 may include a first drift region 230 disposed in the substrate 202 adjacent to a first side portion 215A of the gate electrode 214, a second drift region 240 disposed in the substrate 202 adjacent to a second side portion 215B of the gate electrode 214, a drain region 250 electrically connected with the first drift region 230, and a source region 260 electrically connected with the second drift region 240.

The substrate 202 may include a well region 204 having a first conductivity type, and the gate electrode structure 210 may disposed on the well region 204. The first drift region 230, the second drift region 240, the drain region 250 and the source region 260 may be disposed in the well region 204. Particularly, the drain region 250 may be disposed in the first drift region 230 and the source region 260 may be disposed in the second drift region 240. Device isolation regions 206 may be disposed on both sides of the drain and source regions 250 and 260.

The first drift region 230, the second drift region 240, the drain region 250 and the source region 260 may have a second conductivity type. For example, when a p-type well region is used, the first drift region 230, the second drift region 240, the drain region 250 and the source region 260 may be n-type impurity regions. Alternatively, when an n-type well region is used, the first drift region 230, the second drift region 240, the drain region 250 and the source region 260 may be p-type impurity regions.

The gate electrode 214 may have first openings 214A vertically formed at the first side portion 215A of the gate electrode 214, which is disposed adjacent to the first drift region 230, and second openings 214B vertically formed at the second side portion 215B of the gate electrode 214, which is disposed adjacent to the second drift region 240. Further, first and second insulating patterns 216 and 218 may be disposed in the first and second openings 214A and 214B, respectively. Particularly, the first and second openings 214A and 214B may pass through the first and second side portions 215A and 215B of the gate electrode 214, and the first and second insulating patterns 216 and 218 may be disposed on the gate insulating layer pattern 212.

The first and second openings 214A and 214B may have a slit shape extending along first and second side surfaces of the gate electrode 214, which are disposed adjacent to the drain region 250 and the source region 260, as shown in FIG. 5, and may be filled with the first and second insulating patterns 216 and 218. Meanwhile, the gate electrode structure 210 may include gate spacers 220 disposed on the first and second side surfaces of the gate electrode 214. The gate spacers 220 may be made of an insulating material such as silicon oxide and/or silicon nitride, and the first and second insulating patterns 216 and 218 may be made of the same material as the gate spacers 220.

The first insulating patterns 216 may be disposed over an edge portion of the first drift region 230, and the parasitic capacitance between the gate electrode 214 and the first drift region 230 may thus be reduced. Further, the second insulating patterns 218 may be disposed over an edge portion of the second drift region 240, and the parasitic capacitance between the gate electrode 214 and the second drift region 240 may thus be reduced. As a result, the RC delay of the high voltage semiconductor device 200 and the interference with adjacent devices may be significantly reduced, for the same reasons previously described with respect to the single-sided embodiments of FIGS. 1-3.

As shown in FIGS. 4 and 5, two first insulating patterns 216 and two second insulating patterns 218 are used. However, the number of the first and second insulating patterns 216 and 218 may be variously changed, and thus the scope of the present disclosure is not limited thereto.

The gate electrode structure 210 may be formed by film forming processes and patterning processes. For example, a gate insulating layer may be formed by a thermal oxidation process and a gate conductive layer may be formed by a chemical vapor deposition process. The gate insulating layer may be made of silicon oxide and the gate conductive layer may be made of impurity doped polysilicon.

The gate electrode 214 and the first and second openings 214A and 214B may be formed by patterning the gate conductive layer, and the gate insulating layer pattern 212 may be formed by patterning the gate insulating layer.

After forming the gate electrode 214 and the gate insulating layer pattern 212, a second insulating layer may be formed on the substrate 202 by a chemical vapor deposition process, and an anisotropic etching process may be performed to form the gate spacers 220. For example, the gate spacers 220 may be made of silicon oxide and/or silicon nitride. Particularly, the first and second openings 214A and 214B may be filled with the silicon oxide and/or silicon nitride while forming the second insulating layer, and the first and second insulating patterns 216 and 218 may be obtained by the anisotropic etching process.

That is, the first and second insulating patterns 216 and 218 may be simultaneously formed with the gate spacers 220, and thus no additional processes for forming the first and second insulating patterns 216 and 218 are required. As a result, an increase in manufacturing cost that may be caused by sequentially forming the first and second insulating patterns 216 and 218 is prevented.

The first and second drift regions 230 and 240 may be formed by an ion implantation process using dopants having the second conductivity type before the gate electrode structure 210 is formed. The drain region 250 and the source region 260 may be formed by an ion implantation process using dopants having the second conductivity type after the gate electrode structure 210 is formed.

FIG. 6 is a plan view illustrating another example of the gate electrode and the first and second insulating patterns, as an alternative to the pattern depicted in FIG. 5.

Referring to FIG. 6, a gate electrode 270 may have a plurality of first openings 270A disposed along a first side surface of the gate electrode 270 which is disposed adjacent to the drain region 250, and a plurality of first insulating patterns 272 may be each disposed in the first openings 270A. Further, the gate electrode 270 may have a plurality of second openings 270B disposed along a second side surface of the gate electrode 270 which is disposed adjacent to the source region 260, and a plurality of second insulating patterns 274 may be each disposed in the second openings 270B.

Although the high voltage semiconductor devices 100 and 200 have been described with reference to specific embodiments, they are not limited thereto. Therefore, it will be readily understood by those skilled in the art that various modifications and changes can be made thereto without departing from the spirit and scope of the present disclosure defined by the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. §112(f) are not to be invoked unless the specific terms “means for” or “step for” are recited in a claim.

1. A gate electrode structure comprising:
a gate insulation layer pattern disposed on a substrate, the substrate having a drift region;
a gate electrode disposed on the gate insulating layer pattern such that the gate insulating layer pattern is positioned between the gate electrode and the drift region, the gate electrode having at least one opening at a first side portion thereof configured to reduce a capacitance between the gate electrode and the drift region; and
at least one insulating pattern disposed in the at least one opening.

2. The gate electrode structure of claim 1, further comprising gate spacers disposed on side surfaces of the gate electrode.

3. The gate electrode structure of claim 2, wherein the at least one insulating pattern is made of the same material as the gate spacers.

4. The gate electrode structure of claim 1, wherein the gate electrode has at least one second opening disposed at a second side portion opposite to the first side portion.

5. The gate electrode structure of claim 4, further comprising at least one second insulating pattern disposed in the at least one second opening.

6. The gate electrode structure of claim 1, wherein the at least one opening has a slit shape extending along a first side surface of the gate electrode.

7. The gate electrode structure of claim 1, wherein the gate electrode has a plurality of openings disposed along a first side surface of the gate electrode and a plurality of insulating patterns is each disposed in the plurality of the openings.

8. A high voltage semiconductor device comprising:
a gate insulation layer pattern disposed on a substrate;
a gate electrode disposed on the gate insulating layer pattern;
a drift region disposed in the substrate adjacent to a first side portion of the gate electrode such that the gate insulating layer pattern is arranged between the gate electrode and the drift region;
a drain region electrically connected with the drift region; and
a source region disposed in the substrate adjacent to a second side portion of the gate electrode,
wherein the gate electrode has at least one opening disposed at the first side portion and at least one insulating pattern is disposed in the at least one opening, such that a capacitance between the gate electrode and the drift region is reduced.

9. The high voltage semiconductor device of claim 8, wherein the at least one insulating pattern is disposed on the gate insulating layer pattern.

10. The high voltage semiconductor device of claim 8, wherein the at least one insulating pattern is disposed over an edge portion of the drift region.

11. The high voltage semiconductor device of claim 8, further comprising gate spacers disposed on side surfaces of the gate electrode.

12. The high voltage semiconductor device of claim 11, wherein the at least one insulating pattern is made of the same material as the gate spacers.

13. The high voltage semiconductor device of claim 8, wherein the at least one opening has a slit shape extending along a first side surface of the gate electrode.

14. The high voltage semiconductor device of claim 8, wherein the gate electrode has a plurality of openings disposed along a first side surface of the gate electrode and a plurality of insulating patterns is each disposed in the plurality of the openings.

15. A high voltage semiconductor device comprising:
a gate insulation layer pattern disposed on a substrate;
a gate electrode disposed on the gate insulating layer pattern;
a first drift region disposed in the substrate adjacent to a first side portion of the gate electrode such that the gate insulating layer pattern is arranged between the gate electrode and the first drift region at the first side portion;
a second drift region disposed in the substrate adjacent to a second side portion of the gate electrode such that the gate insulating layer pattern is arranged between the gate electrode and the second drift region at the second side portion;
a drain region electrically connected with the first drift region; and
a source region electrically connected with the second drift region,
wherein the gate electrode has at least one first opening disposed at the first side portion and at least one second opening disposed at the second side portion;
at least one first insulating pattern is disposed in the at least one first opening, such that a capacitance between the gate electrode and the first drift region is reduced; and
at least one second insulating pattern is disposed in the at least one second opening, such that a capacitance between the gate electrode and the second drift region is reduced.

16. The high voltage semiconductor device of claim 15, wherein the first and second insulating patterns are disposed on the gate insulating layer pattern.

17. The high voltage semiconductor device of claim 15, wherein the at least one first insulating pattern is disposed over an edge portion of the first drift region, and the at least one second insulating pattern is disposed over an edge portion of the second drift region.

18. The high voltage semiconductor device of claim 15, further comprising gate spacers disposed on side surfaces of the gate electrode.

19. The high voltage semiconductor device of claim 18, wherein the first and second insulating patterns are made of the same material as the gate spacers.

20. The high voltage semiconductor device of claim 15, wherein the drain and source regions are disposed in the first and second drift regions, respectively.
